(19) United States
(12) Patent Application Publication
(10) Pub. No.: US 2021/0249169 A1
(43) Pub. Date: Aug. 12, 2021

(54) PLATED COPPER CONDUCTOR STRUCTURES AND MANUFACTURE THEREOF

(71) Applicants: DUPONT ELECTRONICS, INC., Wilmington, DE (US); ROHM AND HAAS ELECTRONIC MATERIALS LLC, Marlborough, MA (US)

(72) Inventors: Gregory Scott Blackman, Media, PA (US); Mehrdad Mehdizadeh, Avondale, PA (US); Wei Wu, Hockessin, DE (US); Benjamin Naab, Marlborough, MA (US); Patricia Gumbley, Marlborough, MA (US); Michael Rousseau, Marlborough, MA (US)

(21) Appl. No.: 17/084,558

(22) Filed: Oct. 29, 2020

Related U.S. Application Data
(60) Provisional application No. 62/972,900, filed on Feb. 11, 2020.

(51) Int. Cl. H01F 5/00; H01F 41/04

(52) U.S. Cl. CPC H01F 5/003; H01F 41/043

(57) ABSTRACT

A conductive structure is fabricated on a substrate (either flexible or rigid) by first printing a precursor seed layer of a conductive ink, then electroplating a highly conductive metal such as Cu or Ag onto the precursor. The plated layer has a conductivity approaching that of the bulk metal. To improve the uniformity of plating, an intervening layer of electroless metal may be deposited onto the precursor prior to electroplating.

### FIELD OF THE INVENTION

The present disclosure relates to copper conductive structures fabricated on a variety of substrates and a method for their manufacture. More particularly, the structures are manufactured by printing a thin layer of a conductive paste or ink on the substrate in a preselected pattern and then plating a layer of copper onto the conductive ink pattern to increase the conductance of the pattern. The patterns provide conductors usefully incorporated in a variety of electrical circuits in which high conductivity is beneficial.

### TECHNICAL BACKGROUND

Conductive structures disposed on a non-conductive or insulating substrate are used in a wide variety of electrical and electronic devices. The substrates include both rigid and flexible sheets of both inorganic and organic materials, with polymeric substrates being very common. The sizes of the structures in use span a wide range.

Despite the numerous techniques that have been used to manufacture these devices, there remain challenges for improving manufacturing cost and efficiency, increasing sustainability through prudent use of valuable materials, and creating complex structures that have acceptable electrical properties while being robust during manufacture and end use.

### SUMMARY

An aspect of the present disclosure provides a conductive structure situated on an insulating substrate having first and second opposing major surfaces, the conductive structure having a preselected pattern and comprising:
(a) a first layer of conductive ink having the preselected pattern and adhered to the first major surface; and;
(b) a second layer of electroplated copper situated atop the first layer.

Another aspect provides a process for fabricating a conductive structure on a major surface of an insulating substrate having first and second opposing major surfaces, the process comprising the steps of:
(a) printing a layer of conductive ink in a preselected pattern on the first major surface; and
(b) electroplating copper onto the ink to form the conductive structure.

### BRIEF DESCRIPTION OF THE DRAWINGS

The invention will be more fully understood and further advantages will become apparent when reference is made to the following detailed description of the preferred embodiments of the invention and the accompanying drawings, wherein like reference numerals denote similar elements throughout the several views and in which:

FIG. 1 depicts schematically a conductive structure of the invention having the form of an Archimedean spiral; and

FIG. 2 depicts schematically a conductive structure of the invention having the form of a rectangular spiral.

### DETAILED DESCRIPTION

Various aspects of the present disclosure relate to a conductive structure fabricated by first depositing a conductive ink on a substrate in a preselected pattern, then electroplating the deposited ink with a highly conductive metal to provide the overall conductive structure with increased thickness, and thus conductivity. Other aspects relate to a process for the manufacture of the conductive structure and end uses thereof.

One approach for fabricating complex conductive structures on substrates is widely practiced in the manufacture of either rigid or flexible circuit boards. A thin copper foil is laminated onto the entire surface of a substrate that can be either rigid (such as a fiberglass-reinforced epoxy sheet) or flexible (such as a thin polyimide film). Then a pattern representing the desired final configuration of conductive traces is formed by photolithographic techniques. Areas of the copper foil where conductor is not wanted are dissolved by a chemical etchant, leaving behind the desired pattern. Approaches of this type are ordinarily termed “subtractive.” Very intricate patterns can be formed because of the sophistication of available photolithography methods. The copper used has high intrinsic conductivity, approaching the best levels attainable with bulk copper, and the traces ordinarily can be made with sufficient thickness by starting with a relatively thick foil laminate. Nevertheless, subtractive processes typically are expensive and create a large volume of liquid waste that is usually hazardous and toxic. The copper can be recovered, but at the cost of reducing copper ions in the liquid back to metallic copper.

Alternatively, traces of copper or other conductive metal having a desired configuration can be formed by cutting the desired pattern out of a sheet by known mechanical scribing or cutting techniques or by laser-assisted cutting techniques, then removing material in the other areas. Although the scrap created by these methods is still the conductive metal, considerable rework or reprocessing may be required to reuse the scrap.

It would therefore be beneficial to have manufacturing techniques capable of directly creating a structure with the desired final configuration or a close approximation to it. Such techniques are often termed “additive;” the resulting structures may be described as “net shape” or “near net shape.” Additive techniques are already known for some end uses. For example, structures may be created using a wide range of printing methods that deposit a conductive ink in any desired pattern. Such printing methods include ink-jet, stencil, screen, and three-dimensional printing.

However, the electrical performance attainable with printed ink is limited. Conductive inks ordinarily contain finely divided powders of a conductive material dispersed in a carrier liquid or solvent that may include a binder or other beneficial substances. The best conductivity is obtained with inks having a high proportion of a highly conductive metal powder. After deposition, the carrier liquid is typically removed by drying, either at ambient temperature or under modest heating. The deposited pattern derives its conductivity through a percolative path defined by contact between adjacent particles. For this reason, silver-based inks are preferred, because silver particles resist surface oxidation or other corrosion, so there is ordinarily less contact resistance at the interfaces between contiguous particles. However, copper is sometimes used. For either, the contact attainable results in a conductivity well below the intrinsic conductivity of a solid conductor of the same metal, because of both the limited total area of actual interparticle contact and interfacial resistance due to any surface oxidation. A conductivity of this low level is adequate for some applications, such as shielding, but applications that must sustain high current densities may not be viable. While the resistance of a structure could in principle be decreased by printing an ink layer wider or thicker (or both), there are practical limits. As thickness increases, it is difficult to avoid cracks or other defects that negate the potential reduction in effective resistance. Design considerations may limit the allowable width of a conductive trace.

In some end uses, the conductivity of a printed paste or ink is enhanced by a heat treatment of the deposit at a temperature high enough to cause sintering of adjacent metal particles. But most polymeric substrates cannot withstand the temperatures needed for any sintering to occur, which is typically several hundred degrees Celsius.

The present inventors have found an alternative approach that provides high conductivity without requiring a high temperature heat treatment. The desired pattern is first formed by printing and possibly drying a relatively thin layer of conductive ink, such as a silver-based ink, to form a precursor structure or seed layer, which is then used as a cathode for a copper plating operation. The plating can be carried out to produce a relatively thick layer of copper that closely replicates the geometry of the ink pattern and attains a conductivity level approaching that of bulk copper. Plating with silver is alternatively contemplated herein, but ordinarily the far lower cost of copper suggests its use.

As is known in the art, electroplating is carried out to deposit metal from an anode onto a cathode provided as a workpiece to be plated. In an implementation of the present method, the terminals of an electric power source are connected respectively to one or more Cu metal anodes and the cathode. Here, the cathode is provided initially by the precursor conductive seed layer. The anode(s) and cathode are immersed in an electrolytic plating bath, such as an aqueous H₂SO₄ solution with dissolved Cu ions. Current flows from the supply to the anode(s), through the plating bath to the cathode, and then back to the supply, with copper atoms being removed from the anode and deposited onto the cathode.

In an embodiment, the conductive ink in the precursor must have, at minimum, a thickness sufficient to establish a conductive path that provides electrical continuity through the entire precursor, so that the desired configuration can be fully plated. The required ink thickness depends on the particular ink used, but a 10 μm layer is often convenient. In various embodiments, the resistivity of the conductive ink used is at most about 30, 50, 75, or 100 μΩ·cm. Certain implementations result in a conductive ink layer having a sheet resistance that is at most about 0.02, 0.03, 0.05, 0.07, or 0.1 Ω/square.

The conductivity of plated copper is ordinarily at least an order of magnitude or more larger than that of a typical conductive ink, so that a plating of even 1 μm or more may markedly enhance the conductivity of the finished structure. The resulting structure has sufficient total conductance to function adequately in a variety of end uses that could not be implemented viably using only printed conductors. In various embodiments, the electroplated layer has a thickness of at least 5, 10, 15, 20, 50, 75, 100, 150, or 200 μm, with the preferred thickness depending in part on the conductance required for a particular circuit application. In an embodiment, the thickness is an average value taken over the entire conductive structure. Ideally, the electroplated layer has a relatively smooth surface. In practice, the quality of the plated layer begins to deteriorate as thickness increases beyond certain limits. For example, the surface of plated layers of both copper and silver becomes undesirably nodular, internal stress increases (possibly resulting in cracks or other bulk defects), and overall conductivity does not increase commensurately with apparent thickness. Adhesion of the plated metal to the substrate may also be compromised for thick layers.

The present technique provides efficient use of the conductive metals in both the ink precursor and the plating overlay, since the desired configuration is formed directly, without needing to remove any substantial amount of material by etching or as scrap. Because the plated portion closely replicates the initial ink pattern, relatively intricate structures can be created simply and efficiently by using high resolution printing methods to form the precursor.

The conductive structure can have any convenient pattern that covers a portion, or even substantially all, of a major surface of the substrate. The high conductivity of the structure renders it suitable for use in a wide variety of circuits, either as a circuit element itself or as a conductor that electrically connects two or more circuit components of any type.

The present conductive structure can be fabricated on a variety of non-conductive substrates, including ones that are both rigid and flexible. Suitable rigid substrates include both inorganic and organic/polymeric base materials. Inorganic materials include, without limitation, silica, alumina, silicon, silicon carbide, quartz, glass, and GaAs/GaN semiconductors. Organic materials include, without limitation, various rigid polymeric materials and polymer composite materials that include inorganic filler materials. One exemplary composite material is sold commercially by DuPont de Nemours, Inc., Wilmington, Del., as CORIAN® solid surface material, which comprises a polymethylmethacrylate (PMMA) matrix and alumina trihydrate. Also usable is a fiberglass-reinforced epoxy sheet of the type commonly used in fabricating printed circuit boards.

The present structure can also be fabricated on a variety of foam board materials. Suitable boards include, without limitation, closed-cell polystyrene foam boards available from Dow Chemical, Midland, Mich. in grades designated as STYROFOAM™ Highload 40, 60, or 100 Extruded Polystyrene, depending on their compression strength. In some embodiments, the board or other insulating layer is nominally rigid, but sufficiently thin to retain some degree of flexibility, so that it can be used over substrates that are not completely flat.

Depending on the end-use application, the conductive structure can be manufactured on any plastic material that can be blown into foam. Suitable thermoplastics include polyolefins and alkenyl aromatic polymers. Suitable polyolefins include polyethylene and polypropylene. Suitable alkenyl aromatic polymers include polystyrene and copolymers of styrene and other monomers. Suitable polyethylenes include those of high, medium, low, linear low, and ultra low density types. It is also possible to form foam boards from thermoset polymers such as polyisocyanurate or rigid polyurethane.

In an embodiment, the substrate comprises a foam structure of an alkenyl aromatic polymer material. Suitable alkenyl aromatic polymer materials include alkenyl aromatic homopolymers and copolymers of alkenyl aromatic compounds and copolymerizable ethylenically unsaturated comonomers. The alkenyl aromatic polymer material may further include minor proportions of non-alkenyl aromatic polymers. The alkenyl aromatic polymer material may be comprised solely of one or more alkenyl aromatic homopolymers, one or more alkenyl aromatic copolymers, a blend of one or more of each of alkenyl aromatic homopolymers and copolymers, or blends of any of the foregoing with a non-alkenyl aromatic polymer. Regardless of composition, the alkenyl aromatic polymer material comprises greater than 50 and preferably greater than 70 weight percent alkenyl aromatic monomeric units. In some embodiments, the alkenyl aromatic polymer material is comprised entirely of alkenyl aromatic monomeric units.

Suitable alkenyl aromatic polymers include those derived from alkenyl aromatic compounds such as styrene, alphamethylstyrene, ethylstyrene, vinyl benzene, vinyl toluene, chlorostyrene, and bromostyrene. A preferred alkenyl aromatic polymer is polystyrene. Minor amounts of monoethylenically unsaturated compounds such as C2-6 alkyl acids and esters, ionomeric derivatives, and C4-6 dienes may be copolymerized with alkenyl aromatic compounds. Examples of copolymerizable compounds include acrylonitrile, acrylic acid, methacrylic acid, ethacrylic acid, maleic acid, itaconic acid, maleic anhydride, methyl acrylate, ethyl acrylate, isobutyl acrylate, n-butyl acrylate, methyl methacrylate, vinyl acetate and butadiene, in amounts consistent with maintaining desired properties, such as an adequately low water retention behavior. Embodiments beneficially comprise greater than 80 percent of polystyrene and can be made entirely of polystyrene.

In some embodiments, the foam structure incorporates one or more additives, such as inorganic fillers, nucleating agents, pigments, antioxidants, acid scavengers, infrared attenuators, ultraviolet absorbers, flame retardants, processing aids, extrusion aids, and the like. The foam board may be closed cell or open cell according to ASTM D2856-87.

Suitable flexible polymeric sheet materials include, without limitation, polyimide, polyethylene terephthalate, polycarbonate, and polyolefin materials. Other useful flexible substrates include fibrous polymers, of which one representative example is a moisture vapor-permeable, flash spun, plexifilamentary, high density polyethylene sheet available commercially from DuPont de Nemours, Inc., under the tradename TYVEK®. The present process is especially beneficial in fabricating conductive structures on rough substrates, such as fibrous materials like the foregoing TYVEK® sheet, as it is difficult with conventional techniques to form a continuous and conductive precursor using other techniques, such as electroless deposition without an initial ink deposit. The chemistry of the plating bath, including its constituents and pH, should be compatible with the substrate material.

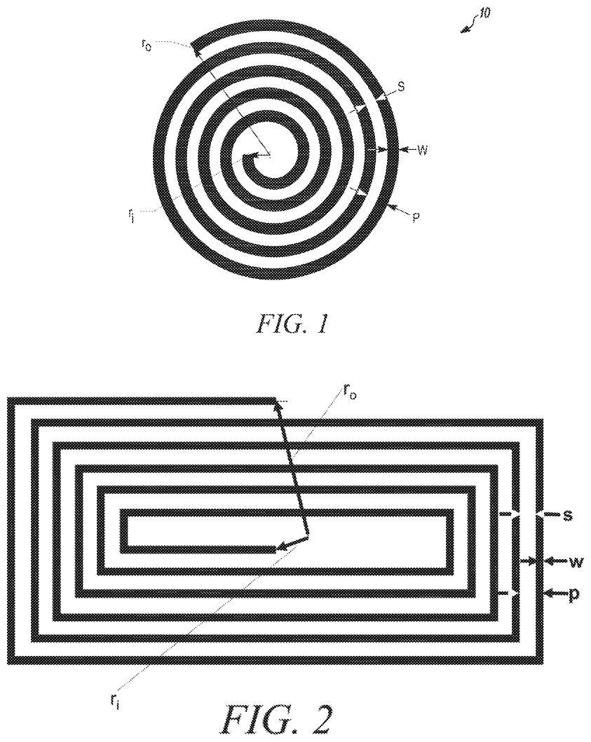

In some embodiments, the present conductive structure is elongated, meaning that its length is much larger than its width. In various embodiments, the ratio of length to width may be at least 50, 100, 300, 500, 1000, or 2000. For example, an elongated structure may have the form of a spiral comprising a plurality of turns. As used herein, the term “spiral” is based on the conventional mathematical sense of a locus defined by the path of a point in a plane that starts at an inner beginning point and moves around a central point while receding from it. The inner beginning point may, but need not, be the same as the central point. The conductive structure is formed by an unbroken conductive trace that follows the locus of the spiral. In some spiral forms used for the present structure, the recession from the center point is continuous. One common form with a continuous and constant recession is conventionally termed an “Archimedean spiral,” as depicted generally at 10 in FIG. 1. Such a spiral is defined by an inner diameter n, an outer diameter rₒ, a trace width w, and a pitch P, which are measured as indicated. S is spacing between loops. Together, specifying these parameters results in a number of turns N.

Alternatively, the recession from the center of the spiral occurs turn by turn instead of continuously. For example, in the rectangular spiral depicted in FIG. 2, each point within a given turn in the spiral is spaced from the comparable point in an adjacent turn by a fixed distance. Although depicted in FIG. 2 with corners that are right-angled, a rectangular spiral might also be configured with rounded corners. S is spacing between loops, P is pitch, w is trace width, rᵢ is inner diameter and rₒ is outer diameter. Other planar spiral forms that a skilled artisan will recognize, such as a square spiral comparable to the foregoing rectangular spiral, are also contemplated for the present conductive structure.

Spiral-form conductive structures are beneficially used in applications in which a substantial inductance is desired. The use in a circuit of an inductor having conductors produced by the present printing/plating process is enhanced by its decreased resistance.

However, it has been found difficult to maintain a uniform thickness in the present conductive structures if the configuration includes a very long trace, whether straight or curved. For example, elongated traces are present in many spiral structures, as described above. Without being bound by any theory, it is believed that the thickness variation is attributable to variation in the total effective electrical impedance of the plating circuit seen by different portions along the length of the trace. In particular, the internal resistance of an elongated seed layer of material with relatively low inherent conductivity can form an appreciable fraction of the total impedance. Therefore, the electrical potential at each point at the bath-cathode interface during plating decreases with distance along the seed layer length from the point of connection to the power supply. The local potential at a given point affects both the initial nucleation of Cu deposits and the Cu deposition rate thereafter. It is believed that the plating is initiated near the connection point, where the potential is highest, with an initiation front that then advances along the trace length. Behind the initiation front, sufficient Cu is soon deposited to shunt and mitigate the low conductivity of the initial seed layer, so that the local potential does not decrease as much with distance away from the connection point. Subsequent to the initial nucleation, the deposition rate behind the advancing front, as measured normal to the substrate, is relatively consistent. Therefore, after any given plating duration, the plated layer is thickest near the connection point and progressively thinner going away from it. The disparity can be reduced by providing a higher conductivity seed layer, so that the initiation front moves more rapidly through the full extent of the precursor area, minimizing the portion of the plating cycle during which deposition is inhibited. Theoretical modeling by de Leeuw et al., Synthetic Metals 66 263-273 (1994), suggests that the rate of advance of the initiation front is approximately inversely proportional to the square root of the sheet resistance of the seed layer. The uniformity can also be improved by making direct connections can be made at a plurality of points along the precursor, so that there are multiple initiation fronts that need only to move over a shorter distance before full coverage is obtained and uniform deposition can thereafter occur. For example, connection might be made at both ends of a spiral structure, or at additional points along the extent of such a structure. The thickness disparity also becomes less pronounced as the overall plated thickness increases.

In some embodiments, the thickness variation may be further mitigated by reducing or eliminating the organic brightener frequently included in the coper plating bath.

In an embodiment, the thickness of the trace after the electroplating is substantially uniform, meaning that a ratio of the highest thickness along an extended trace to the lowest thickness is at most 6:1, 5:1, 4:1, 2:1, or 1.5:1. In a further embodiment, this ratio has any of the foregoing values and the lowest thickness along the trace is at least 2, 5, 10, 15, 20, or 50 μm. In still another embodiment, the ratio has any of the foregoing values and the highest thickness along the trace is at most 20, 50, 75, 100, 150, or 200 μm. The thickness in these embodiments may be measured using a variety of techniques. For example, the thickness may be measured by an x-ray fluorescence (XRF) technique, in which a fluorescent intensity is compared between the trace and a reference sample of the same material and known thickness. The XRF technique is non-destructive, and beneficially provides an average thickness over the local region illuminated by the x-ray beam. The thickness is also measurable non-destructively using scanning confocal microscopy, such as with a Keyence VK-X260K 3D Laser Scanning Confocal Microscope. In addition, traces may be measured destructively using micrographs taken in cross-section.

In some implementations, the foregoing problem of the low conductivity of the printed ink pattern and the ensuing variation of plated thickness is mitigated by disposing a metal enhancement layer between the conductive ink and the electroplated metal. This can be effected by an electroless plating step carried out before the electroplating step. The electroless plating step deposits additional metal, including without limitation copper or nickel, onto the printed ink pattern. For example, the added metal can provide additional connectivity between discrete particles within the printed pattern, which is especially beneficial for inks with low metal loading. The resulting improvement in the precursor's conductivity may improve the uniformity of the plated layer. In some embodiments, the addition of electroless metal can even bridge gaps across which the initial conductive ink deposit fails to provide conductivity. Without being bound by any theory, it is believed that metal particles in the initial conductive ink may act as catalytic sites that nucleate the deposition of electroless metal. Suitable electroless processes are ones in which metal is deposited only on the seed layer and possibly at its margins, and not in a more widespread layer encompassing most or all of the substrate.

### EXAMPLES

The operation and effects of certain embodiments of the present invention may be more fully appreciated from the examples described below. The embodiment on which these examples are based is representative only, and the selection of these embodiments to illustrate aspects of the invention does not indicate that materials, components, conditions, techniques and/or configurations not described are not suitable for use herein, or that subject matter not described in the examples is excluded from the scope of the appended claims and equivalents thereof.

### Example 1

### Fabrication of a Conductive Structure on a Polyolefin Sheet Substrate

A conductive structure having the form of an Archimedean spiral, as depicted schematically in FIG. 1, was fabricated on a sheet of a TYVEK® polyethylene sheet, Type 10-1056DR (available from DuPont de Nemours, Inc., Wilmington, Del.). For Example 1, the spiral structure used had dimensions of n=16 mm, rₒ=60 mm, w=2 mm, and P=4 mm/turn, and a total of 11 turns. The resulting length of the conductive trace was about 2.6 m, so the ratio of length to width was about 1300.

TYVEK® sheets (about 160 μm thick) were prepared in the form of 15 cm square coupons. A pattern of silver-containing conductive ink (PE828 ATM006, available from DuPont de Nemours, Inc., Wilmington, Del.) having the shape shown in FIG. 1 was printed on each using an AIM885 screen printer, with a thickness of about 13 μm. The printed pattern was cured in a box oven at 80° C. for 30 min with circulating air flow, thereby providing a precursor. The manufacturer represents this ink as having a resistivity of about 45 μΩ·cm after curing, so that a 13 μm layer exhibits a sheet resistance of about 0.034 Ω/square.

Thereafter, the silver ink pattern of the precursor was electroplated with copper to increase the conductance of the spiral. First, the ink surface was activated by a short predip of the coupon in a 10% sulfuric acid bath, then the sheet was placed in a plating bath of 35-75 g/L Cu₂SO₄.5H₂O, 180-225 g/L H₂SO₄, and 35-65 ppm Cl⁻ (in the form of HCl) in H₂O. Organic brightener was maintained between 0.05 and 10 ppm and the carrier maintained at 500-2500 ppm. The silver ink was the cathode for the plating operation, with the power supply being connected to both the inside and outside ends of the spiral. The bath contained soluble Cu anodes. An operating temperature of 22-28° C. was maintained, with air, solution and paddle agitation throughout the plating cycle. Plating current densities of 10-30 ASF (amps per square foot) were used. A plating time of 4 h with a 20 ASF plating current resulted in a structure with a thickness of ˜38 μm averaged over the length of the spiral.

Representative electrical properties measured for the bare silver ink of the precursor spiral and for the finished Cu-plated spiral are set forth in Table I.

TABLE I
Electrical Properties of Spiral Coil

| | Printed Ag | Ag + E-plated Cu |
|---|---|---|
| Averaged thickness <t> (μm) | ~13 | ~38 |
| Electrical resistance R (Ω) @100 Hz | 45 | 0.58 |
| Inductance (μH) @10 KHz | 9 | 8.9 |

DC resistance values were measured using a standard four-probe method. The resistance R_{Cu} of the Cu layer itself (without the printed Ag seed layer) was calculated by assuming the measured total resistance R to be a parallel combination of the resistances of the bare Ag layer and the plated Cu layer. Then, assuming the Cu layer to have the resistivity ρ of pure Cu (1.7 μΩ·cm), and using the measured length/and width w of the spiral, the averaged thickness <t> of the plated Cu was calculated using the standard formula

$${R}_{C u} = \frac{ρ l}{w 〈 t 〉} .$$

Inductance was measured using a BK Precision® LCR Meter Model 879B.

As evident in Table I, the principal effect of the plating is to lower the resistance of the coil by almost two orders of magnitude. The inferred average thickness <t>=38 μm is consistent with XRF measurements of the trace, which showed a thickness of ˜100 μm at the connection points at the inner and outer ends and ˜20 μm near the midpoint of the spiral length, which is most distant from the connection points. If the effective resistivity of the plated Cu is higher than the 1.7 μΩ·cm of bulk Cu, then the actual average thickness would be proportionately higher. Whereas the resistivity of the printed Ag is well below that of bulk Ag or Cu, the plated Cu trace has a resistivity approaching the value for high-purity, annealed bulk Cu. Both the increased thickness and the improved inherent low resistivity obtained in the plated copper trace are believed to contribute to the marked lowering of resistance.

Having thus described the invention in rather full detail, it will be understood that this detail need not be strictly adhered to but that further changes and modifications may suggest themselves to one skilled in the art, all falling within the scope of the invention as defined by the subjoined claims.

The embodiments of the conductive structure described herein, including the examples, are not limiting; it is contemplated that one of ordinary skill in the art could make minor substitutions and not substantially change the desired properties and its functioning in a system.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

Certain terminology may be employed herein for clarity and convenience of description, rather than for any limiting purpose. For example, the terms “forward,” “rearward,” “right,” “left,” “top,” “bottom,” “upper,” and “lower” designate directions in the drawings to which reference is made. The various drawings may depict the present components oriented in a convenient configuration. Terminology of similar import other than the words specifically mentioned above likewise is to be considered as being used for purposes of convenience rather than in any limiting sense.

What is claimed is:

1. A conductive structure situated on an insulating substrate having first and second opposing major surfaces, the conductive structure having a preselected pattern and comprising:
(a) a first layer of conductive ink having the preselected pattern and adhered to the first major surface; and
(b) a second layer of electroplated metal situated atop the first layer.

2. The conductive structure of claim 1, wherein the conductive ink contains silver.

3. The conductive structure of claim 1 or claim 2, wherein the conductive ink layer has a sheet resistance of at most 0.1 Ω/square.

4. The conductive structure of any preceding claim, wherein the metal of the second layer comprises copper.

5. The conductive structure of any preceding claim, wherein the average thickness of the second layer is at least 10 μm.

6. The conductive structure of any preceding claim, wherein the conductive structure has a substantially uniform thickness.

7. The conductive structure of any preceding claim, wherein the conductive structure has a length and a width, and a ratio of the length to the width is at least 50.

8. The conductive structure of any preceding claim, further comprising an electroless metal enhancement layer situated between the first and second layers.

9. The conductive structure of claim 8, wherein the metal enhancement layer comprises copper.

10. The conductive structure of any preceding claim, wherein the substrate is flexible.

11. The conductive structure of claim 10, wherein the substrate is a plexifilamentary, high density polyethylene sheet.

12. The conductive structure of claim 10, wherein the substrate is a polyimide.

13. The conductive structure of any of claims 1 to 9, wherein the substrate is a rigid sheet.

14. The conductive structure of claim 13, wherein the substrate is a polymethylmethacrylate-containing composite.

15. The conductive structure of any preceding claim, having the form of a spiral comprising a plurality of turns.

16. A process for fabricating a conductive structure on a major surface of an insulating substrate having first and second opposing major surfaces, the process comprising the steps of:
(a) printing a first layer of conductive ink in a preselected pattern on the first major surface; and
(b) electroplating a second layer of metal onto the ink to form the conductive structure.

17. The process of claim 16, wherein the conductive ink contains silver.

18. The process of any of claims 16 to 17, wherein the first layer has a sheet resistance of at most 0.1 Ω/square.

19. The process of any of claims 16 to 18, wherein the electroplated metal comprises copper.

20. The process of claim 19, wherein sufficient copper is electroplated such that the second layer has an average thickness of at least 10 μm.

21. The process of any of claims 16 to 20, wherein the conductive structure has a substantially uniform thickness.

22. The process of any of claims 16 to 21, wherein the conductive structure has a length and a width, and a ratio of the length to the width is at least 50.

23. The process of any of claims 16 to 22, wherein the electroplating is carried out using a power source that is connected to the conductive ink at a plurality of points.

24. The process of any of claims 16 to 23, further comprising the step of electrolessly depositing an electroless metal enhancement layer onto the conductive ink, the step being carried out between the printing and electroplating steps.

25. The process of claim 24, wherein the electroless metal enhancement layer comprises copper.

26. The process of any of claims 16 to 25, wherein the substrate is flexible.

27. The process of claim 26, wherein the substrate is a plexifilamentary, high density polyethylene sheet.

28. The process of any of claims 16 to 25, wherein the substrate is a rigid sheet.

29. The process of claim 28, wherein the substrate is a polymethylmethacrylate-containing composite.
